(19) United States
(12) Patent Application Publication
(10) Pub. No.: US 2015/0072440 A1
(43) Pub. Date: Mar. 12, 2015

(54) METHOD OF MANUFACTURING MAGNETORESISTIVE ELEMENT

(71) Applicants: Satoshi INADA, Yokohama-shi (JP); Kazuhiro TOMIOKA, Seoul (KR); Satoshi SETO, Seoul (KR); Masatoshi YOSHIKAWA, Seoul (KR)

(72) Inventors: Satoshi INADA, Yokohama-shi (JP); Kazuhiro TOMIOKA, Seoul (KR); Satoshi SETO, Seoul (KR); Masatoshi YOSHIKAWA, Seoul (KR)

(21) Appl. No.: 14/201,108

(22) Filed: Mar. 7, 2014

Related U.S. Application Data
(60) Provisional application No. 61/875,478, filed on Sep. 9, 2013.

(51) Int. Cl. H01L 43/12; H01L 21/3065

(52) U.S. Cl. CPC H01L 43/12; H01L 21/3065
USPC 438/3

(57) ABSTRACT

According to one embodiment, a method of manufacturing a magnetoresistive element, the method includes forming a non-magnetic layer on a first magnetic layer, forming a second magnetic layer on the non-magnetic layer, and patterning the second magnetic layer by a RIE using an etching gas including a noble gas and a hydrocarbon gas.

### CROSS-REFERENCE TO RELATED APPLICATIONS

This application claims the benefit of U.S. Provisional Application No. 61/875,478, filed Sep. 9, 2013, the entire contents of which are incorporated herein by reference.

### FIELD

Embodiments described herein relate generally to a method of manufacturing a magnetoresistive element.

### BACKGROUND

An MRAM (magnetic random access memory) chip employed as a nonvolatile semiconductor storage uses a magnetoresistive element as a storage element. The magnetoresistive element has a structure in which a tunnel barrier layer (non-magnetic layer) is sandwiched between a storage layer (magnetic layer) and a reference layer (magnetic layer).

### BRIEF DESCRIPTION OF THE DRAWINGS

FIG. 1 is a cross-sectional view showing an example of a magnetoresistive element of a first embodiment;

FIG. 2 is a cross-sectional view showing an example of a magnetoresistive element of a second embodiment;

FIG. 3 to FIG. 8 are cross-sectional views showing a manufacturing method of the magnetoresistive element shown in FIG. 2;

FIG. 9 to FIG. 11 are block diagrams showing an example of a multi-chamber;

FIG. 12 is an illustration showing an example of a manufacturing device executing RIE;

FIG. 13 is a block diagram showing an example of a magnetic random access memory; and

FIG. 14 is a cross-sectional view showing an example of a memory cell.

### DETAILED DESCRIPTION

In general, according to one embodiment, a method of manufacturing a magnetoresistive element, the method comprises: forming a non-magnetic layer on a first magnetic layer; forming a second magnetic layer on the non-magnetic layer; and patterning the second magnetic layer by a RIE using an etching gas including a noble gas and a hydrocarbon gas; and patterning the non-magnetic layer and the first magnetic layer after patterning the second magnetic layer.

The embodiments will be hereinafter described with reference to the attached drawings.

### First Embodiment

FIG. 1 shows a magnetoresistive element of First Embodiment.

First magnetic layer 11 is disposed on underlayer UL. Non-magnetic layer 12 is disposed on first magnetic layer 11. Second magnetic layer 13 is disposed on non-magnetic layer 12. Hard mask layer HM is disposed on second magnetic layer 13.

Second magnetic layer 13 is patterned by, for example, RIE using an etching gas including a noble gas and a hydrocarbon gas, and using hard mask layer HM as a mask. In other words, second magnetic layer (for example, CoFeB, etc.) 13 is etched by the noble gas, and generates a carbon compound by reacting with carbon in the hydrocarbon gas.

For this reason, patterning of second magnetic layer 13 of the present embodiment can enhance etching anisotropy as compared with, for example, RIE using halogen gas.

In addition, the patterning is executed while generating the carbon compound, and non-magnetic layer (for example, MgO, etc.) 12 does not react with carbon in the hydrocarbon gas. Since the carbon compound is deposited on a surface of non-magnetic layer 12 at the time when the surface of non-magnetic layer 12 is exposed, non-magnetic layer 12 is protected by this deposit.

Accordingly, in the patterning of second magnetic layer 13, non-magnetic layer 12 serving as a base of second magnetic layer 13 can be prevented from being etched.

For example, when one of first magnetic layer 11 and second magnetic layer 13 is a storage layer having variable magnetization and the other is a reference layer having invariable magnetization, stopping the etching of second magnetic layer 13 on the surface of non-magnetic layer (tunnel barrier layer) 12, what is called “stop on tunnel barrier” can be executed.

Side wall insulating layers SWM are formed on side walls of second magnetic layer 13 after patterning second magnetic layer 13. First magnetic layer 11 is patterned by, for example, RIE using a noble gas, and using hard mask layer HM and side wall insulating layers SWM as masks, after forming side wall insulating layers SWM.

First magnetic layer 11 and second magnetic layer 13 may be in a perpendicular magnetization type having perpendicular magnetization or an in-plane magnetization type having in-plane magnetization.

The etching gas used for the patterning of first magnetic layer 11 and second magnetic layer 13 may contain nitrogen gas, hydrogen gas, etc. It is desirable, however, that these gases should not contain oxygen gas or an oxygen compound gas to prevent oxidization of first magnetic layer 11 and second magnetic layer 13.

Furthermore, an interface layer (magnetic layer) may be disposed between first magnetic layer 11 and non-magnetic layer 12, and between non-magnetic layer 12 and second magnetic layer 13. In this case, the interface layer between non-magnetic layer 12 and second magnetic layer 13 is etched by RIE using an etching gas including a noble gas and hydrocarbon gas, similarly to second magnetic layer 13.

Accordingly, the etching of second magnetic layer 13 can be certainly stopped when the surface of non-magnetic layer 12 is exposed, as compared with, for example, executing the patterning of second magnetic layer 13 by physical etching (for example, IBE), RIE using halogen gas, etc.

### Second Embodiment

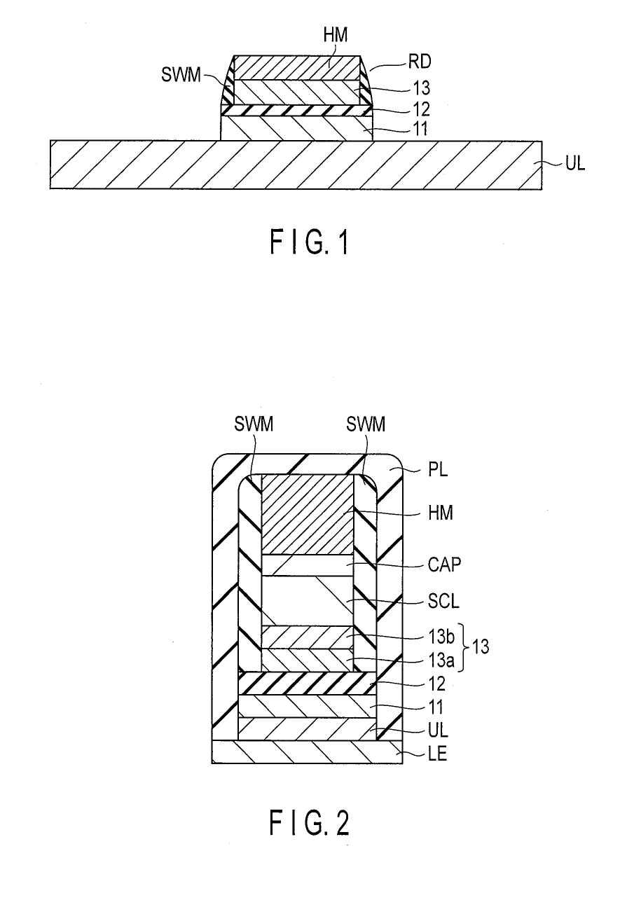

FIG. 2 shows a magnetoresistive element of Second Embodiment.

Underlayer UL is disposed on lower electrode LE, first magnetic layer 11 is disposed on underlayer UL, non-magnetic layer (tunnel barrier layer) 12 is disposed on first magnetic layer 11, and second magnetic layer 13 is disposed on non-magnetic layer 12. Second magnetic layer 13 may comprise layers such as first layer 13a and second layer 13b or may be a single layer.

Shift cancel layer SCL is disposed on second magnetic layer 13. Shift cancel layer SCL can cancel a stray magnetic field applied from second magnetic layer 13 onto first magnetic layer 11 when, for example, first magnetic layer 11 is a storage layer and second magnetic layer 13 is a reference layer.

Shift cancel layer SCL thus comprises a magnetic layer having a perpendicular and invariable magnetization direction, similarly to the reference layer. The invariable magnetization direction indicates that the magnetization direction is invariable to a predetermined write current.

Cap layer CAP is disposed on shift cancel layer SCL. Hard mask layer HM is disposed on cap layer CAP.

Hard mask layer HM is of, for example, W, Ta, TaN, Ti, TiN, etc. Cap layer CAP is of, for example, Pt, W, Ta, Ru, etc. Shift cancel layer SCL is of, for example, CoPt, CoMn, CoPd, etc.

First layer 13a in second magnetic layer 13 is of, for example, CoFeB, etc. Second layer 13b in second magnetic layer 13 is of, for example, CoPt, CoMn, CoPd, etc. Non-magnetic layer 12 is of, for example, MgO, AlO, etc. First magnetic layer 11 is of, for example, CoFeB, etc.

Underlayer UL is of, for example, Hf, AlN, TaAlN, etc. Lower electrode LE is of, for example, W, Ta, TaN, Ti, TiN, etc.

The structure shown in FIG. 2 is formed by, for example, a first etching process using hard mask layer HM as a mask and a second etching process using hard mask layer HM and side wall insulating layers (side wall mask layers) SWM as masks.

In the first etching process, cap layer CAP, shift cancel layer SCL, and second magnetic layer 13 are etched. In the second etching process, non-magnetic layer 12, first magnetic layer 11, and underlayer UL are etched. Protective layer PL is formed after the first and second etching processes.

Each of Side wall mask layers SWM and protective layer PL comprises, for example, an insulator layer of silicon nitride, silicon oxide, etc.

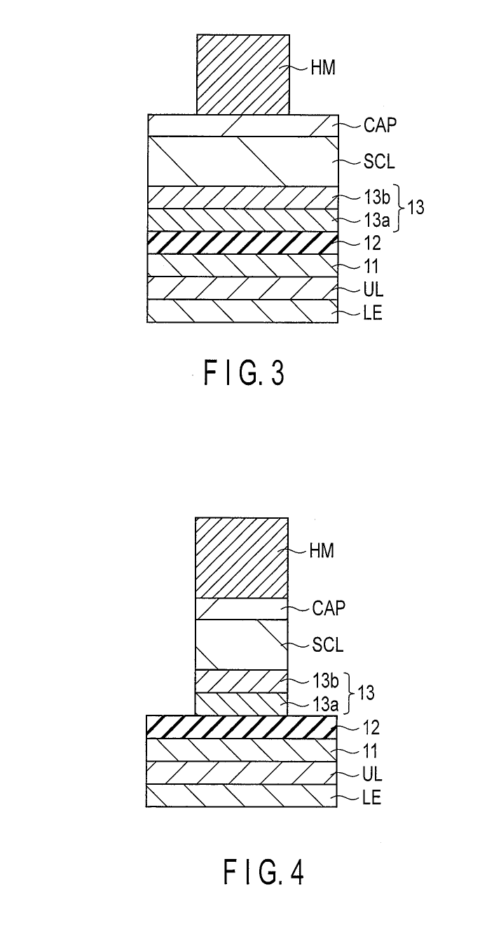

FIG. 3 to FIG. 8 show an example of a manufacturing method for obtaining the structure shown in FIG. 2.

First, underlayer UL is formed on lower electrode LE, first magnetic layer 11 is formed on underlayer UL, non-magnetic layer (tunnel barrier layer) 12 is formed on first magnetic layer 11, and second magnetic layer 13 is formed on non-magnetic layer 12, as shown in FIG. 3. Second magnetic layer 13 comprises first layer 13a and second layer 13b.

Subsequently, shift cancel layer SCL is formed on second magnetic layer 13, cap layer CAP is formed on shift cancel layer SCL, and hard mask layer HM is formed on cap layer CAP.

Next, a first patterning process is executed as shown in FIG. 4. In the first patterning process, cap layer CAP, shift cancel layer SCL and second magnetic layer 13 are etched by using hard mask layer HM as a mask. The first patterning process will be described later.

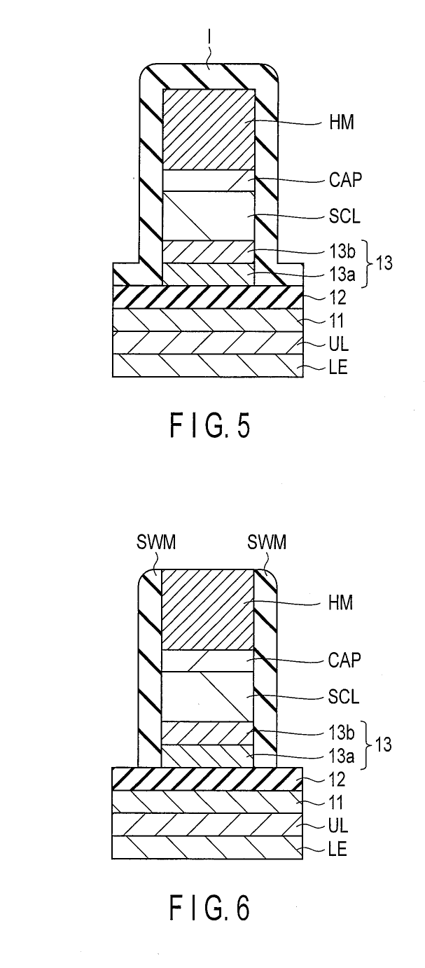

Next, insulating layer (for example, silicon nitride) I to cover hard mask layer HM, cap layer CAP, shift cancel layer SCL, and second magnetic layer 13 is formed by, for example, CVD, as shown in FIG. 5.

Subsequently, side wall insulating layers (side wall mask layers) SWM to cover the side walls of hard mask layer HM, cap layer CAP, shift cancel layer SCL, and second magnetic layer 13 are formed by etching insulating layer I, by the etching method such as IBE and RIE, as shown in FIG. 6.

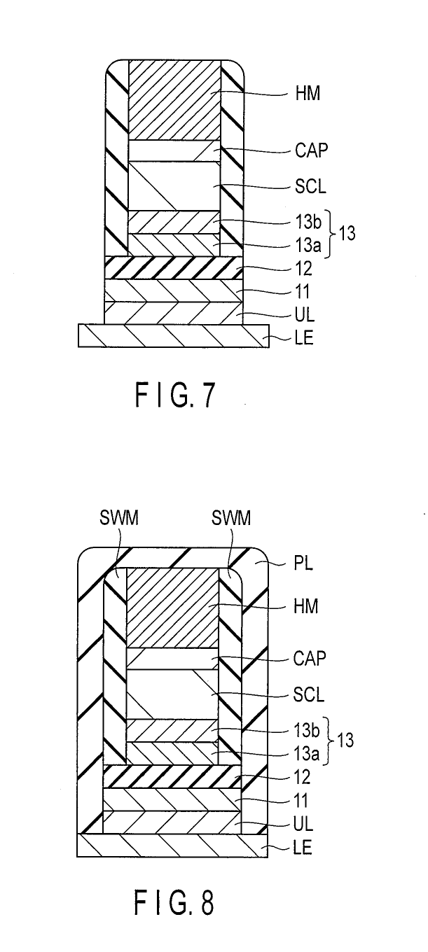

Next, a second patterning process is executed as shown in FIG. 7. In the second patterning process, non-magnetic layer 12, first magnetic layer 11 and underlayer UL are etched by using hard mask layer HM and side wall mask layers SWM as masks. The details of the second etching process will be described later.

Finally, protective layer (for example, silicon nitride) PL to cover the magnetoresistive element is formed on lower electrode LE as shown in FIG. 8.

The structure shown in FIG. 2 is completed in the above-described steps.

The first patterning process will be described here.

The first patterning process is a process for sequentially etching cap layer CAP, shift cancel layer SCL, and second magnetic layer 13 as shown in FIG. 4.

In the Second Embodiment, at least the etching of first layer 13a in second magnetic layer 13 in contact with non-magnetic layer 12 is executed by RIE using an etching gas containing a noble gas and hydrocarbon gas. In the first patterning process, what is called “stop on tunnel barrier” is thereby executed certainly.

Table 1 shows a first example of combination of the etching methods which can be employed in the first patterning process.

TABLE 1

| First Patterning process | | | A | B | C |
|---|---|---|---|---|---|
| Upper layer ↑ | Cap layer CAP | | RIE | IBE | IBE |
| Layer | Shift cancel layer SCL | | with noble | RIE | RIE |
| Lower layer ↓ | Second magnetic | Second layer 13b | gas and | with noble | with noble |
| | layer 13 | First layer 13a | hydrocarbon | gas and | gas and |
| | | | gas | hydrocarbon | hydrocarbon |
| | | | | gas | gas |

In Case A, in Table 1, all of cap layer CAP, shift cancel layer SCL, and second magnetic layer 13 are etched by the RIE using an etching gas including a noble gas and hydrocarbon gas. If all of the layers are thus etched by the RIE using the etching gas including a noble gas and hydrocarbon gas, the first patterning process can be completed in a single chamber. Advantages such as simplification of the process and reduction of the manufacturing costs can be therefore achieved.

In Case B, in Table 1, cap layer CAP and shift cancel layer SCL are etched by physical etching, for example, IBE and, subsequently to this, second magnetic layer 13 is etched by the RIE using the etching gas including a noble gas and hydrocarbon gas.

According to this combination, cap layer CAP and shift cancel layer SCL are etched by the physical etching. The physical etching is superior to the RIE in view of an etching anisotropy and an etching speed.

Therefore, advantages such as improvement of accuracy in processing the magnetoresistive element and reduction of the etching time can be achieved by etching these layers that are not in contact with the non-magnetic layer (tunnel barrier layer) by the physical etching.

In this combination, however, two different etching methods, i.e., physical etching and RIE, are employed. For this reason, to execute the first patterning process, the magnetoresistive element (wafer) needs to be conveyed from a first chamber in which the physical etching is executed to a second chamber in which the RIE is executed.

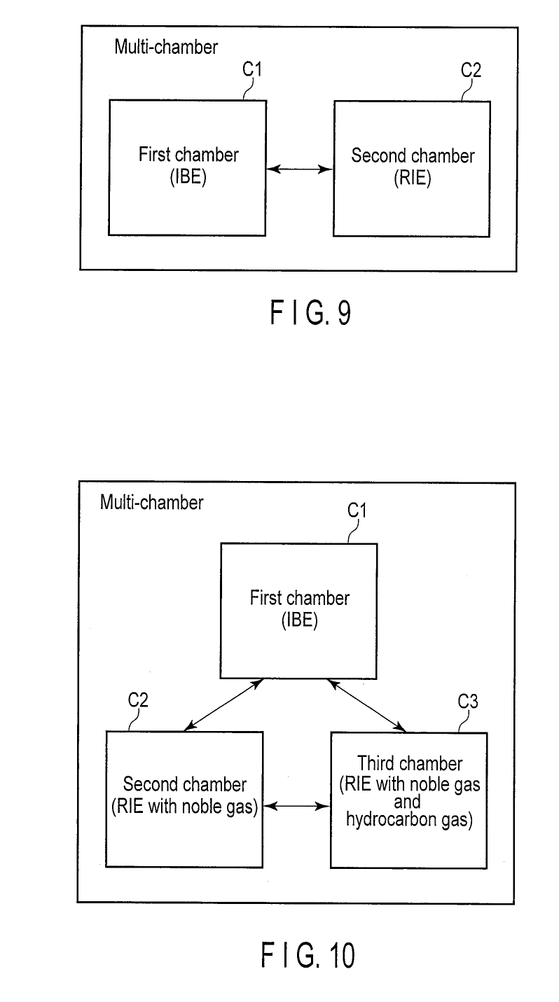

Thus, in Case B, a multi-chamber comprising first chamber C1 in which the physical etching is executed and second chamber C2 in which the RIE is executed is prepared as shown in, for example, FIG. 9, when the first patterning process is executed.

In the multi-chamber, the magnetoresistive element (wafer) is conveyed from first chamber C1 to second chamber C2 in a state in which the magnetoresistive element is not exposed to air, i.e., the magnetoresistive element is not oxidized.

In Case C, in Table 1, each of cap layer CAP, shift cancel layer SCL, and second layer 13b in second magnetic layer 13 is etched by the physical etching, for example, IBE and, subsequently to this, first layer 13a in second magnetic layer 13 is etched by the RIE using the etching gas including a noble gas and hydrocarbon gas.

According to this combination, not only cap layer CAP and shift cancel layer SCL, but second layer 13b in second magnetic layer 13 are etched by the physical etching. Therefore, in Case C, the same advantages as those in Case B can be achieved, and the accuracy in processing the magnetoresistive element can be more improved and the etching time can be more reduced than those in Case B.

Table 2 shows a second example of combination of the etching methods which can be employed in the first patterning process.

TABLE 2

| First Patterning process | | | D | E |
|---|---|---|---|---|
| Upper layer ↑ | Cap layer CAP | | RIE | RIE |
| Layer | Shift cancel layer SCL | | with noble gas | with noble gas |
| Lower layer ↓ | Second magnetic | Second layer 13b | (no hydrocarbon gas) | (no hydrocarbon gas) |
| | layer 13 | First layer 13a | RIE | RIE |
| | | | with noble | with noble |
| | | | gas and | gas and |

| | |
|---|---|
| hydrocarbon gas | hydrocarbon gas |

The second example is an example in which the physical etching (IBE) is replaced with the RIE using a noble gas (and not including hydrocarbon gas) in Case B and Case C shown in Table 1.

In Case D, in Table 2, cap layer CAP and shift cancel layer SCL are etched by the RIE using a noble gas and, subsequently to this, second magnetic layer 13 is etched by the RIE using the etching gas including a noble gas and hydrocarbon gas.

According to this combination, at least second magnetic layer 13 in contact with the non-magnetic layer (tunnel barrier layer) is etched by the RIE using the etching gas including a noble gas and hydrocarbon gas. In the first patterning process, what is called “stop on tunnel barrier” can be therefore executed certainly.

In addition, all of cap layer CAP, shift cancel layer SCL and second magnetic layer 13 are etched by the RIE in this combination. Thus, if the first patterning process is completed in a single chamber by changing the etching gas in the chamber, advantages such as the simplification of the process and the reduction of manufacturing costs can be achieved.

In Case D, too, however, the first patterning process may be executed in first chamber C1 in which the RIE using a noble gas is executed and second chamber C2 in which the RIE using the etching gas including a noble gas and hydrocarbon gas, as shown in FIG. 9.

In this case, the magnetoresistive element (wafer) is conveyed from first chamber C1 to second chamber C2 in a state in which the magnetoresistive element is not exposed to air, i.e., the magnetoresistive element is not oxidized.

In Case E, in Table 2, each of cap layer CAP, shift cancel layer SCL, and second layer 13b in second magnetic layer 13 is etched by the RIE using a noble gas and, subsequently to this, first layer 13a in second magnetic layer 13 is etched by the RIE using the etching gas including a noble gas and hydrocarbon gas.

According to this combination, not only cap layer CAP and shift cancel layer SCL, but second layer 13b in second magnetic layer 13 are etched by the RIE using a noble gas. Therefore, in Case E, the same advantages as those in Case D can be achieved.

Table 3 shows a third example of combination of the etching methods which can be employed in the first patterning process.

TABLE 3

| First Patterning process | | | F | G |
|---|---|---|---|---|
| Upper layer ↑ | Cap layer CAP | | IBE | IBE |
| Layer | Shift cancel layer SCL | | RIE | RIE |
| Lower layer ↓ | Second magnetic | Second layer 13b | with noble gas | with noble gas |
| | layer 13 | First layer 13a | (no hydrocarbon gas) | (no hydrocarbon gas) |
| | | | RIE | RIE |
| | | | with noble | with noble |

| | |
|---|---|
| hydrocarbon gas | hydrocarbon gas |

The third example is an example in which the first patterning process is executed by three etching methods, i.e., physical etching (IBE), RIE using a noble gas (and not including hydrocarbon gas), and RIE using an etching gas including a noble gas and hydrocarbon gas.

In Case F, in Table 3, cap layer CAP is etched by the physical etching, for example, the IBE and shift cancel layer SCL is etched by the RIE using a noble gas and, subsequently to this, second magnetic layer 13 is etched by the RIE using the etching gas including a noble gas and hydrocarbon gas.

According to this combination, at least second magnetic layer 13 in contact with the non-magnetic layer (tunnel barrier layer) is etched by the RIE using the etching gas including a noble gas and hydrocarbon gas. In the first patterning process, what is called “stop on tunnel barrier” can be therefore executed certainly.

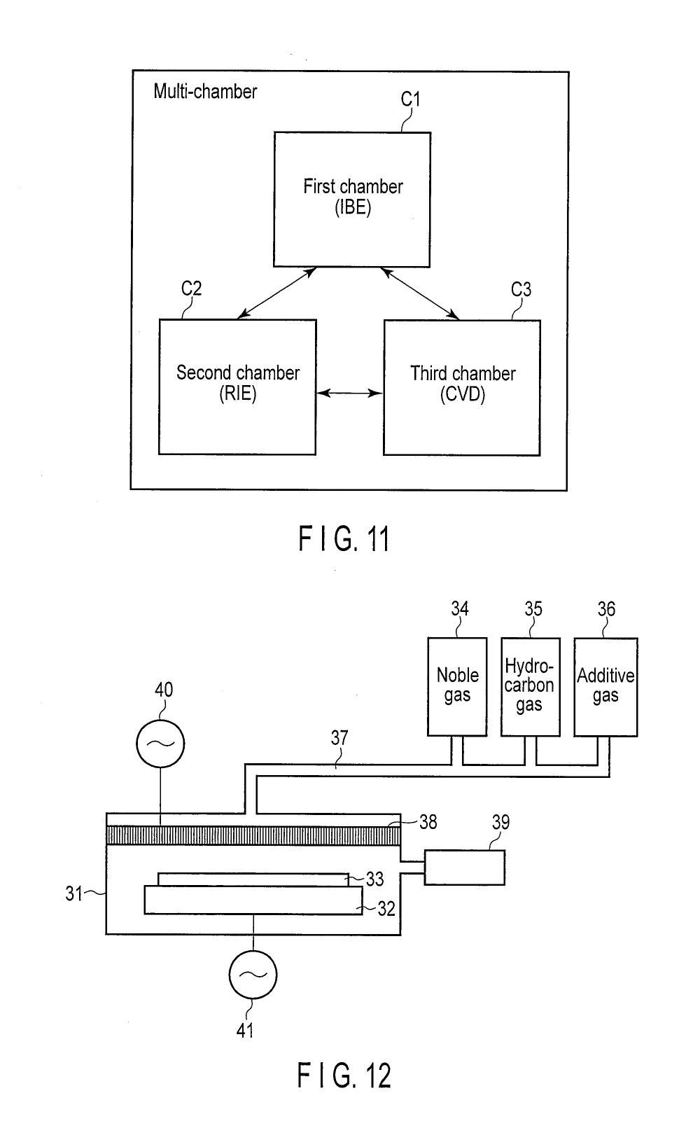

In this combination, three different etching methods, i.e., the physical etching, RIE using a noble gas, and RIE using the etching gas including a noble gas and hydrocarbon gas are employed. For this reason, to execute the first patterning process, a multi-chamber comprising first chamber C1 in which the physical etching is executed, second chamber C2 in which the RIE using a noble gas is executed, and third chamber C3 in which the RIE using a noble gas and hydrocarbon gas is executed, is prepared as shown in, for example, FIG. 10.

In the multi-chamber, the magnetoresistive element (wafer) is conveyed among first chamber C1, second chamber C2 and third chamber C3 in a state in which the magnetoresistive element is not exposed to air, i.e., the magnetoresistive element is not oxidized.

This process can be modified to executing the physical etching in first chamber C1, executing the RIE in second chamber C2, and executing CVD in third chamber C3 as shown in FIG. 11. In this case, third chamber C3 is used for, for example, the processes for forming insulating layer I as shown in FIG. 5.

In addition, the first patterning process of the present embodiment can also be executed by using, for example, first chamber C1 in which the physical etching is executed and second chamber C2 in which the RIE is executed as shown in FIG. 9.

In Case G, in Table 3, cap layer CAP and shift cancel layer SCL are etched by the physical etching, for example, the IBE and second layer 13b in second magnetic layer 13 is etched by the RIE using a noble gas and, subsequently to this, first layer 13a in second magnetic layer 13 is etched by the RIE using the etching gas including a noble gas and hydrocarbon gas.

According to this combination, at least first layer 13a in second magnetic layer 13 in contact with the non-magnetic layer (tunnel barrier layer) is etched by the RIE using the etching gas including a noble gas and hydrocarbon gas. The same advantages as those in Case F can be therefore achieved in Case G.

An example of the etching gas used in the first patterning process will be described here.

The etching gas includes a noble gas and hydrocarbon gas.

The noble gas is, for example, Ar gas or Xe gas. The hydrocarbon gas includes one of methane, ethane, propane, butane, pentane, ethylene, and acetylene.

Desirably, the etching gas is nonoxidative, which indicates that oxygen gas or oxygen compound gas is not included in the etching gas. In addition, the etching gas may include hydrogen gas or nitrogen gas as a reducing gas.

An example of the etching gas is described below:

Noble gas: Ar gas (50 sccm-1,000 sccm)
Hydrocarbon gas: CH₄ gas (10 sccm-200 sccm)
Reducing gas: H₂ gas (5 sccm-500 sccm)
N₂ gas (5 sccm-20 sccm)

A proportion (volume ratio) Ar/CH₄ between Ar gas and CH₄ gas is desirably within a range from 1% to 83% and, further desirably, within a range from 5% to 50%.

In addition, a bias power required to ionize the etching gas is desirably within a range from 50 W to 800 W. In particular, when a 300 mm wafer is used, the bias power is desirably within a range from 100 W to 500 W.

Moreover, a pressure in the chamber in which the RIE is executed is desirably within a range from 5 mT to 300 mT and, further desirably, within a range from 7 mT to 20 mT.

Next, the second patterning process will be described.

The second patterning process is a process for sequentially etching non-magnetic layer 12, first magnetic layer 11 and underlayer UL as shown in FIG. 7.

The second patterning process is executed by a combination of the physical etching, for example, IBE with the RIE using a noble gas (and not including hydrocarbon gas).

Table 4 shows an example of combination of the etching methods which can be employed in the second patterning process.

TABLE 4

| Second patterning process | | A | B | C | D |
|---|---|---|---|---|---|
| Upper layer ↑ | Non-magnetic layer 12 | IBE | RIE | IBE | IBE |
| Layer | First magnetic layer 11 | | | RIE | RIE |
| Lower layer ↓ | Foundation layer UL | | | | |

Since the second patterning process can be executed by well-known technology, descriptions of the process are omitted here.

### Third Embodiment

In Third Embodiment, a method of stopping etching of a second magnetic layer on a non-magnetic layer, or example, certainly controlling “stop on tunnel barrier” when the non-magnetic layer is exposed will be described.

In the First and Second Embodiments (FIG. 1 to FIG. 8), the etching of second magnetic layer 13 on non-magnetic layer 12 is etched by RIE using an etching gas including a noble gas and hydrocarbon gas.

The noble gas (for example, Ar gas) physically etches second magnetic layer 13 by colliding with second magnetic layer 13. In other words, the noble gas is used mainly for the purpose of anisotropically etching second magnetic layer 13.

In addition, the hydrocarbon gas (for example, CH₄ gas) forms a carbon compound (complex) by reacting with transition elements (for example, Co, Fe, etc.) in second magnetic layer 13. In other words, the hydrocarbon gas has an action of etching second magnetic layer 13.

The hydrocarbon gas further has the following action.

When a surface of non-magnetic layer 12 is exposed, in the first patterning process, the hydrocarbon gas is brought into contact with a surface of second magnetic layer 13. However, since the hydrocarbon gas does not react with non-magnetic layer (for example, MgO) 12, non-magnetic layer 12 is not etched by the hydrocarbon gas.

In addition, when the surface of non-magnetic layer 12 is exposed, the carbon compound formed of carbon in the hydrocarbon gas and the transition elements in second magnetic layer 13 is deposited on the surface of non-magnetic layer 12. The carbon compound has an action of preventing non-magnetic layer 12 from being etched by the noble gas.

Thus, an amount of generation (i.e., amount of deposition) of the carbon compound needs to be controlled in order to achieve both the etching anisotropy and the etching selection ratio (“stop on tunnel barrier”).

Thus, the amount of generation of the carbon compound can be controlled based on a flow rate of the hydrocarbon gas, a rate (volume ratio or mass ratio) of carbon atoms in the hydrocarbon gas. For example, the amount of generation of the carbon compound is greater as the flow rate of the hydrocarbon gas is higher and as the rate of carbon atoms in the hydrocarbon gas is higher.

For example, a rate of carbon in propane (C₃H₈) gas is higher than a rate of carbon in methane (CH₄) gas. Accordingly, when propane (C₃H₈) gas is used as the hydrocarbon gas, the amount of generation of the carbon compound is greater than that when methane (CH₄) gas is used as the hydrocarbon gas.

The amount of generation of the carbon compound can be varied in the first patterning process. In Cases A to G in Tables 1-3, for example, the flow rate, type, etc. of the hydrocarbon gas may be controlled such that the amount of generation of the carbon compound after exposure of the surface of the non-magnetic layer (tunnel barrier layer) is greater than the previous amount of generation of the carbon compound.

For example, in Case A in Table 1, the flow rate, type, etc. of the hydrocarbon gas may be controlled such that the amount of generation of the carbon compound at the etching of first layer 13a in second magnetic layer 13 is greater than the amount of generation of the carbon compound at the etching of the other layers.

Under such control, stopping the etching of the second magnetic layer on the non-magnetic layer, for example, “stop on tunnel barrier” is certainly executed when the non-magnetic layer is exposed.

FIG. 12 shows an example of a chamber in which the RIE is executed.

Wafer 33 is arranged on wafer table (electrode) 32 in chamber 31. The noble gas, hydrocarbon gas and additive gas (reducing gas) are supplied from gas suppliers 34, 35, and 36, respectively, into chamber 31 through gas pipe 37. These gases evenly spread on wafer 33 by shower plate (electrode) 38.

A pressure in chamber 31 is measured by pressure gauge 39. High-frequency power supplies 40 and 41 are connected to wafer table 32 and shower plate 38, respectively.

Then, the RIE is executed by generating plasma of the etching gas in chamber 31 and by accelerating ions of the etching gas toward wafer 33 while controlling electric power of high-frequency power supplies 40 and 41 and the pressure in chamber 31.

In such a chamber, the amount of generation of the carbon compound can be controlled in the first patterning process by controlling the flow rate, type, etc. of the hydrocarbon gas supplied into chamber 31.

### (Example of Application)

Application of the magnetoresistive element of the above-described embodiments to a magnetic random access memory will be described here.

A 1T-1MTJ type memory cell array wherein a memory cell comprises a magnetoresistive element and a select transistor will be hereinafter described as one of examples of application.

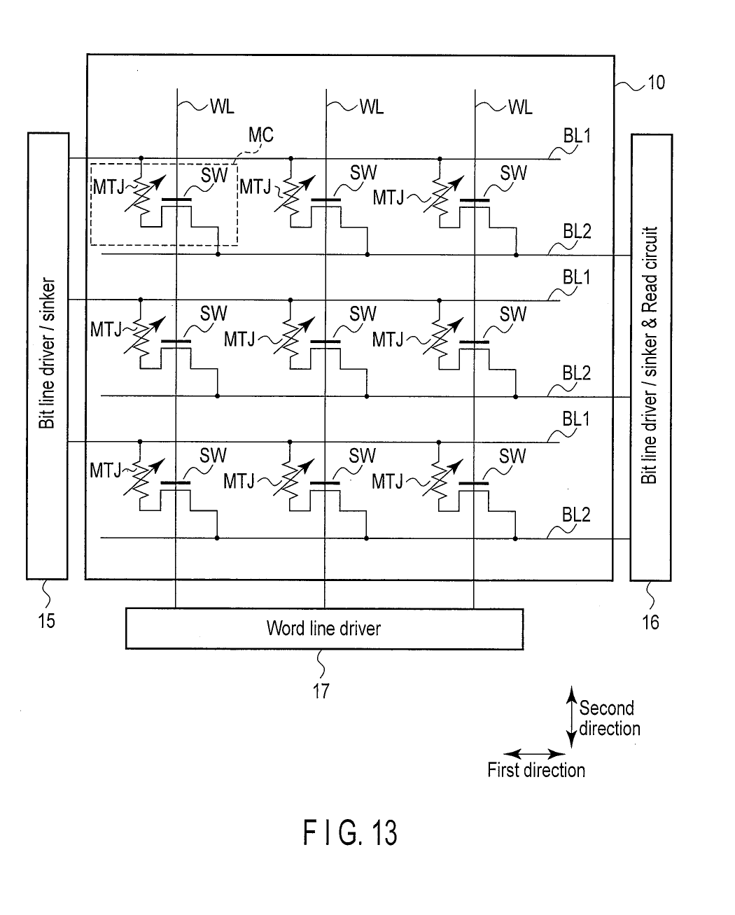

FIG. 13 shows an example of an equivalent circuit of the 1T-1MTJ type memory cell array.

Memory cell array 10 comprises arrayed memory cells MC. Each of memory cells MC comprises magnetoresistive element MTJ and select transistor (FET) SW.

Magnetoresistive element MTJ and select transistor (FET) SW are serially connected, each having an end connected to first bit line BL1 and the other end connected to second bit line BL2. A control terminal (gate terminal) of select transistor SW is connected to word line EL.

First bit line BL1 extends in a first direction, having an end connected to bit line driver/sinker 15. Second bit line BL2 extends in the first direction, having an end connected to bit line driver/sinker and read circuit 16.

However, the circuit may be modified to connect first bit line BL1 to bit line driver/sinker and read circuit 16 and to connect second bit line BL2 to bit line driver/sinker 15.

In addition, bit line driver/sinker 15 and bit line driver/sinker and read circuit 16 may be disposed at positions opposite to each other or the same position.

Word line WL extends in a second direction, having an end connected to word line driver 17.

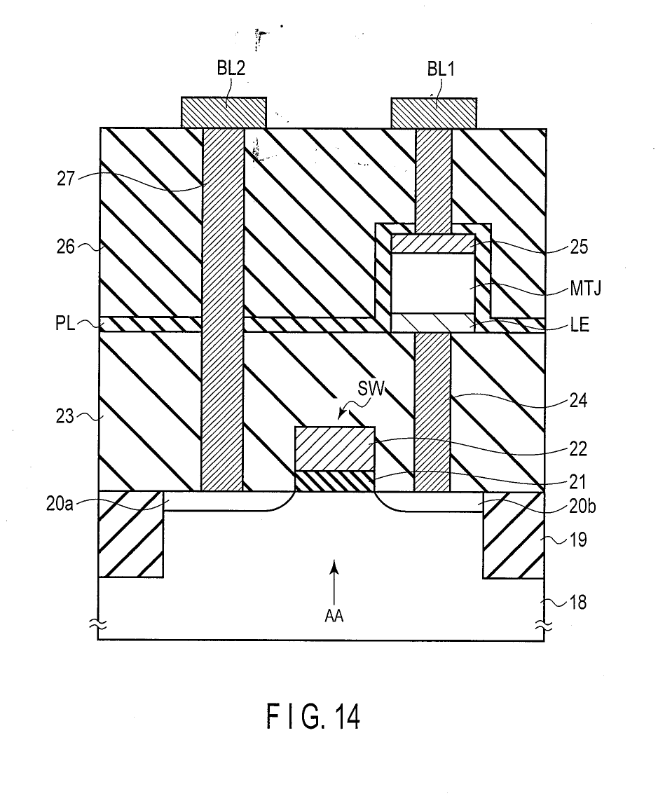

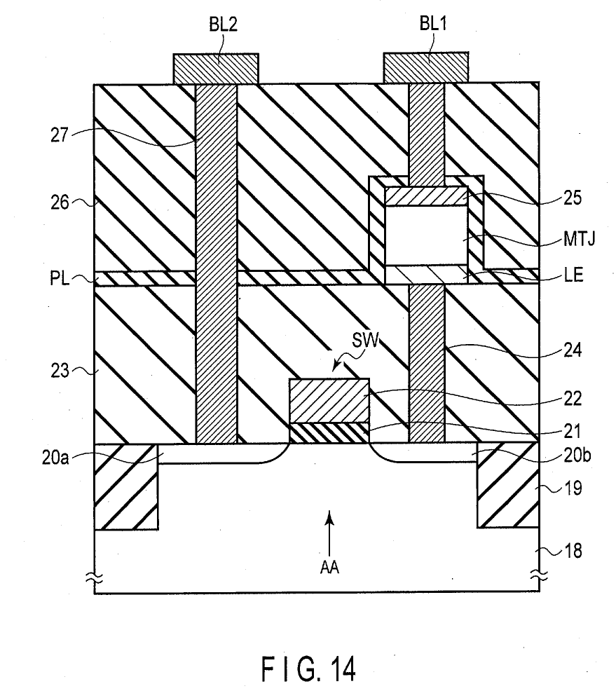

FIG. 14 shows an example of the memory cell.

Select transistor SW is disposed in active area AA in semiconductor substrate 18. Active area AA is surrounded by element isolating/insulating layer 19 in semiconductor substrate 18. In this example, element isolating/insulating layer 19 has an STI (Shallow Trench Isolation) structure.

Select transistor SW comprises source/drain diffusion layers 20a and 20b in semiconductor substrate 18, gate insulation layer 21 on a channel between the layers, and gate electrode 22 on gate insulation layer 21. Gate electrode 22 functions as word line WL.

Interlayer insulation layer 23 covers select transistor SW. A top surface of interlayer insulation layer 23 is flat, and lower electrode LE is disposed on interlayer insulation layer 23. Lower electrode LE is connected to source/drain diffusion layer 20b of select transistor SW via contact plug 24.

Magnetoresistive element MTJ is disposed on lower electrode LE. Upper electrode 25 is disposed on magnetoresistive element MTJ. Upper electrode 25 functions as, for example, hard mask HM to be used for processing of magnetoresistive element MTJ.

Protective layer PL covers the side walls of magnetoresistive element MTJ.

Interlayer insulation layer 26 is disposed on protective layer PL to cover magnetoresistive element MTJ. A top surface of interlayer insulation layer 26 is flat, and first bit line BL1 and second bit line BL2 are disposed on interlayer insulation layer 26. First bit line BL1 is connected to upper electrode 25. Second bit line BL2 is connected to source/drain diffusion layer 20a of select transistor SW via contact plug 27.

### CONCLUSION

According to the above-described embodiments, etching the magnetic layer alone disposed on the tunnel barrier layer, i.e., stopping the etching on the tunnel barrier layer surface (what is called “stop on tunnel barrier”) can be certainly executed, at the two-step patterning of the magnetoresistive element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetoresistive element, the method comprising:
forming a non-magnetic layer on a first magnetic layer;
forming a second magnetic layer on the non-magnetic layer;
patterning the second magnetic layer by a RIE using an etching gas including a noble gas and a hydrocarbon gas; and
patterning the non-magnetic layer and the first magnetic layer after patterning the second magnetic layer.

2. The method of claim 1, wherein
the second magnetic layer comprises a first layer on the non-magnetic layer and a second layer on the first layer, and
the first layer is patterned by the RIE.

3. The method of claim 2, wherein
the first layer contacts the non-magnetic layer.

4. The method of claim 2, wherein
the second layer is patterned by the RIE.

5. The method of claim 2, wherein
the second layer is patterned by a RIE using an etching gas including the noble gas and not including the hydrocarbon gas.

6. The method of claim 2, wherein
the second layer is patterned by a physical etching.

7. The method of claim 6, wherein
the physical etching is a IBE.

8. The method of claim 1, further comprising:
generating a carbon compound from a carbon in the hydrocarbon gas and an element in the second magnetic layer in the patterning of the second magnetic layer.

9. The method of claim 8, wherein
the non-magnetic layer does not etched by being protected by the carbon compound in the patterning the second magnetic layer.

10. The method of claim 1, wherein
the etching gas includes a nitrogen gas.

11. The method of claim 1, wherein
the etching gas includes a hydrogen gas.

12. The method of claim 1, wherein
the etching gas does not include an oxygen gas and a oxygen compound gas.

13. The method of claim 1, wherein
the noble gas is one of an argon gas and a xenon gas, and
the hydrocarbon gas includes one of a methane, an ethane, a propane, a butane, a pentane, an ethylene, and an acetylene.

14. The method of claim 1, wherein
the first magnetic layer is a storage layer with a perpendicular and variable magnetization, and
the second magnetic layer is a reference layer with a perpendicular and invariable magnetization.

15. The method of claim 14, further comprising:
forming a shift cancelling layer on the second magnetic layer; and
patterning the shift cancelling layer by the RIE.

16. The method of claim 14, further comprising:
forming a shift cancelling layer on the second magnetic layer; and
patterning the shift cancelling layer by a RIE using an etching gas including the noble gas and not including the hydrocarbon gas

17. The method of claim 14, further comprising:
forming a shift cancelling layer on the second magnetic layer; and
patterning the shift cancelling layer by a physical etching.

18. The method of claim 1, further comprising:
forming a sidewall insulating layer on a sidewall of the second magnetic layer after patterning the second magnetic layer; and
patterning the first magnetic layer after forming the sidewall insulating layer.

19. The method of claim 5, further comprising:
patterning the second layer by supplying the noble gas in a chamber; and
patterning the first layer by supplying the noble gas and the hydrocarbon gas in the chamber.

20. The method of claim 6, further comprising:
patterning the second layer in a first chamber;
transferring the magnetoresistive element from the first chamber to a second chamber in a state of being non-oxidized the magnetoresistive element; and
patterning the first layer in the second chamber.
